(19) United States
(12) Patent Application Publication
(10) Pub. No.: US 2026/0255597 A1
(43) Pub. Date: Aug. 27, 2026

(54) MANAGING CONTACT STRUCTURES IN THREE-DIMENSIONAL SEMICONDUCTOR DEVICES

(71) Applicant: Yangtze Memory Technologies Co., Ltd., Wuhan (CN)

(72) Inventors: Zhihao SONG, Wuhan (CN); Zhong ZHANG, Wuhan (CN); Yang CHEN, Wuhan (CN); Kun ZHANG, Wuhan (CN)

(21) Appl. No.: 19/175,045

(22) Filed: Apr. 10, 2025

(30) Foreign Application Priority Data
Feb. 25, 2025 (CN) 202510216889.5

(51) Int. Cl. H10B 43/27

(52) U.S. Cl. CPC H10B 43/27

(57) ABSTRACT

Systems, devices, and methods for managing contact structures in a semiconductor device are provided. In one aspect, a semiconductor device includes a memory array structure including a first stack of first dielectric layers and conductive layers alternating with each other and a channel structure extending in the first stack; a connection structure including a second stack of the first dielectric layers and second dielectric layers alternating with each other; and a contact structure extending at least partially in the connection structure and including a first end, a second end and a step structure between the first end and the second end. The first end is coupled to a corresponding conductive layer. The step structure includes a first surface and a second surface intersecting with the first surface. The first surface is between the first end and the second end. The second surface is in contact with the first end.

### CROSS-REFERENCE TO RELATED APPLICATIONS

This application claims priority to Chinese Patent Application No. 202510216889.5, filed on Feb. 25, 2025, which is hereby incorporated by reference in its entirety.

### TECHNICAL FIELD

The present disclosure relates to semiconductor devices and fabrication processes for semiconductor devices.

### BACKGROUND

Semiconductor devices may be classified into non-volatile memory devices, such as flash memory devices, and volatile memory devices, such as dynamic random-access memory (DRAM). The semiconductor memory devices can have different structures with different densities of memory cells and lines on a chip. A memory device normally includes a memory array of memory cells and control circuitries. The control circuitries can facilitate operations of the memory array.

### SUMMARY

The present disclosure describes methods, devices, systems and techniques for managing contact structures in three-dimensional (3D) semiconductor devices.

One aspect of the present disclosure features a semiconductor device, including: a memory array structure including a first stack of first dielectric layers and conductive layers alternating with each other along a first direction and a channel structure extending in the first stack along the first direction; a connection structure including a second stack of the first dielectric layers and second dielectric layers alternating with each other along the first direction; and a contact structure extending at least partially in the connection structure along the first direction and including a first end, a second end and a step structure between the first end and the second end along the first direction, the first end being coupled to a corresponding conductive layer of the conductive layers of the first stack of the memory array structure. The step structure includes a first surface and a second surface intersecting with the first surface, the first surface extends along a second direction different from the first direction and is between the first end and the second end along the first direction, and the second surface is in contact with the first end.

In some implementations, along the second direction, a size of the second end is smaller than an outer size of the step structure.

In some implementations, the outer size of the step structure along the second direction is greater than a size of the first end along the second direction, and the size of the second end along the second direction is smaller than the size of the first end along the second direction.

In some implementations, the semiconductor device includes a slit structure extending along the first direction, where the slit structure includes a first end and a second end opposite to the first end along the first direction, and a surface of the second end of the slit structure is aligned with the first surface of the step structure of the contact structure.

In some implementations, in a plane where the first surface extends, a cross-section of the second end of the contact structure is a first circle, a cross-section of the step structure of the contact structure is a second circle, and where the first circle and the second circle are concentric, and where a diameter of the first circle is smaller than a diameter of the second circle.

In some implementations, the contact structure includes an air gap surrounded by at least one conductive structure.

In some implementations, the contact structure includes a dielectric layer between the air gap and the at least one conductive structure.

In some implementations, the at least one conductive structure includes a first conductive structure and a second conductive structure. The second end of the contact structure includes a portion of the second conductive structure surrounded by a portion of the first conductive structure. Both the portion of the second conductive structure and the portion of the first conductive structure extend along the first direction.

In some implementations, the second end of the contact structure includes a dielectric layer surrounded by a portion of the second conductive structure.

In some implementations, the semiconductor device includes a channel contact coupled to the channel structure, and a conductive material of the channel contact is same as a conductive material of the contact structure.

Another aspect of the present disclosure features a semiconductor device including: a memory array structure including a first stack of first dielectric layers and conductive layers alternating with each other along a first direction and a channel structure extending in the first stack along the first direction; a connection structure including a second stack of the first dielectric layers and second dielectric layers alternating with each other along the first direction; and a contact structure extending at least partially in the connection structure along the first direction and including a first portion and a second portion, the first portion including a first end and a second end opposite to the first end along a first direction, the second end of the first portion being coupled to the second portion. A size of the first end of the first portion along a second direction different from the first direction is smaller than a size of the second end of the first portion along the second direction, and the size of the second end of the first portion is greater than a size of the second portion along the second direction.

In some implementations, the second end of the first portion and the second portion define a step.

In some implementations, the contact structure includes an air gap surrounded by at least one conductive structure.

In some implementations, the contact structure includes a dielectric layer between the air gap and the at least one conductive structure.

In some implementations, the semiconductor device includes a slit structure extending along the first direction. The slit structure includes a first end and a second end opposite to the first end along the first direction, and a surface of the second end of the slit structure is aligned with a surface of the second end of the first portion of the contact structure.

In some implementations, the dielectric layer includes a first part in the first portion of the contact structure and a second part in the second portion of the contact structure. The first part of the dielectric layer is in contact with the second part of the dielectric layer.

Another aspect of the present disclosure features a method including: forming a memory array structure including a first stack of first dielectric layers and conductive layers alternating with each other along a first direction and a channel structure extending in the first stack along the first direction; forming a connection structure including a second stack of the first dielectric layers and second dielectric layers alternating with each other along the first direction; and forming a contact structure extending at least partially in the connection structure and including a first end, a second end and a step structure between the first end and the second end along a first direction, the first end being coupled to a corresponding conductive layer of the conductive layers. The step structure includes a first surface and a second surface intersecting with the first surface. The first surface extends in a second direction different from the first direction and is between the first end and the second end, and the second surface is in contact with the first end.

In some implementations, the method includes forming a channel contact extending in a dielectric interlayer on the memory array structure, the channel contact being coupled to the channel structure, and where a conductive material of the channel contact is same as a conductive material of the contact structure.

In some implementations, the method includes forming a contact structure opening extending in the connection structure; forming a channel contact opening extending in the dielectric interlayer; and depositing a first conductive structure in both the contact structure opening and the channel contact opening.

In some implementations, forming the contact structure opening includes: forming a first portion of the contact structure opening extending in the connection structure along the first direction; depositing a dielectric layer and a sacrificial layer in the first portion; forming a second portion of the contact structure opening; and removing the sacrificial layer in the first portion of the contact structure through the second portion of the contact structure opening, where a size of the first portion of the contact structure opening along a second direction different from the first direction is greater than a size of the second portion of the contact structure opening along the second direction.

In some implementations, forming the contact structure includes: depositing the first conductive structure in the contact structure opening through the second portion of the contact structure opening; and depositing a second conductive structure in the contact structure opening through the second portion of the contact structure opening.

In some implementations, depositing the first conductive structure including: depositing the first conductive structure by atomic layer deposition (ALD).

In some implementations, the method includes: forming first openings between adjacent first dielectric layers of the first dielectric layers in an initial memory array structure; forming second openings between adjacent first dielectric layers of the first dielectric layers in an initial connection structure; and depositing at least one conductive material in the first openings and the second openings to form the conductive layers.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1 illustrates a plan view of an example 3D semiconductor device.

FIG. 2A illustrates a cross-sectional view of a portion of an example connection region of an example semiconductor device including an example contact structure.

FIG. 2B illustrates a cross-sectional view of a portion of an example array region of the example semiconductor device in FIG. 2A.

FIG. 2C is an enlarged view of the example contact structure in FIG. 2A.

FIG. 2D illustrates a plan view of a portion of the example semiconductor device in FIG. 2A.

FIG. 3A illustrates a cross-sectional view of a portion of another example semiconductor device including another example contact structure.

FIG. 3B illustrates a plan view of a portion of the example semiconductor device in FIG. 3A.

FIGS. 4A through 4R illustrate cross-sectional views of an example semiconductor device at various stages of a manufacturing process.

FIG. 5 is a flow chart of an example process to form an example semiconductor device.

FIG. 6 illustrates a block diagram of a system having one or more semiconductor devices.

Like reference numbers and designations in the various drawings indicate like elements. It is to be understood that the various exemplary implementations shown in the figures are merely illustrative representations and are not necessarily drawn to scale.

### DETAILED DESCRIPTION

Memory devices, like NAND flash memory devices, can be configured to pad out gate layers using contact structures. Additionally, the memory devices can couple channel layers in channel structures to a bit line using channel contacts. The contact structures for gate lines and channel contacts for channel layers can couple the NAND memory cells to BEOL (Back-End-of-Line) metal layers. In some cases, the contact structures and the channel contacts can be formed separately in separate process loops, e.g., distinct deposition, patterning, or etching steps for each structure. The separate process loops require additional materials, time, and equipment, making it challenging to streamline the manufacture process and reduce manufacturing costs.

Implementations of the present disclosure provide semiconductor devices and methods for forming such semiconductor devices. In some implementations, a semiconductor device includes a memory array structure including a first stack of first dielectric layers and conductive layers alternating with each other and a channel structure extending in the first stack; a connection structure including a second stack of the first dielectric layers and second dielectric layers alternating with each other; and a contact structure extending at least partially in the connection structure and including a first end, a second end and a step structure between the first end and the second end. The first end is coupled to a corresponding conductive layer. The step structure includes a first surface and a second surface intersecting with the first surface. The first surface is between the first end and the second end. The second surface is in contact with the first end.

Implementations of the present disclosure can provide one or more of the following technical advantages and/or benefits. For example, by forming the channel contact for channel layers and the contact structure for gate layers together, both the manufacturing costs and process complexity can be significantly reduced. Combining these steps reduces the need for separate processes, which would otherwise require additional materials, time, and equipment. The technologies streamline the manufacture flow, allowing for faster production cycles. Moreover, fewer process steps may reduce the likelihood of errors or defects, leading to higher yield. Additionally, in some implementations, the contact structure includes a dielectric layer. The dielectric layer can be deposited into the contact structure opening using the atomic layer deposition (ALD) process. Compared to other deposition processes (e.g., chemical vapor deposition (CVD), or physical vapor deposition (PVD)), ALD may effectively prevent the formation of air gaps or seams close to an upper surface of the contact structure. This can help to avoid exposing air gaps or seams during subsequent chemical mechanical polishing (CMP) processes, thus preventing the internal structure of the contact structure from being exposed.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

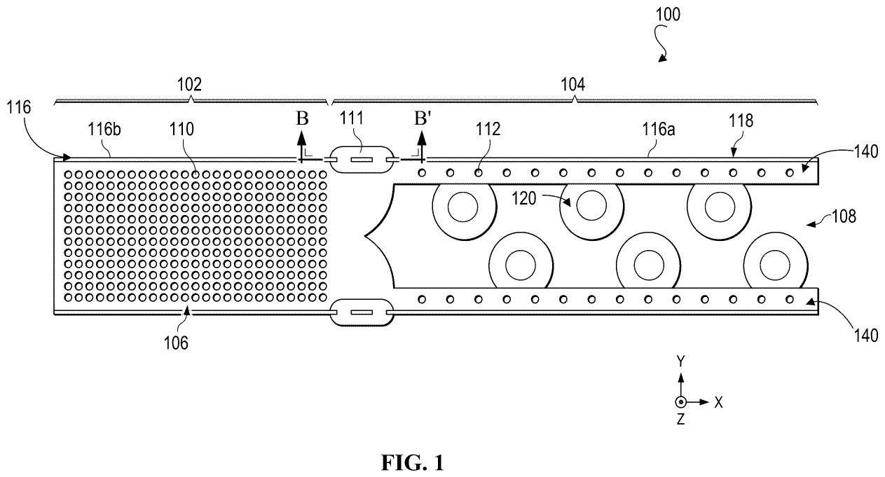

FIG. 1 illustrates a plan view of an example semiconductor device 100. In some implementations, the semiconductor device 100 can be a memory device, such as a three-dimensional (3D) NAND memory device. The semiconductor device 100 can include one or more array regions 102 and one or more connection regions 104 configured to provide conductive connections for the one or more array regions. In some implementations, as shown in FIG. 1, the semiconductor device 100 includes an array region 102 and a connection region 104 adjacent to the array region 102 along a first horizontal direction (e.g., the X direction). It is understood that the example in FIG. 1 is for illustration purpose and is not intended to be construed in a limiting sense. In practice, any suitable arrangement of various regions in the semiconductor device 100 can be applied. In some instances, the semiconductor device 100 can have two connection regions 104 and an array region 102 arranged between the two connection regions 104 along the X direction. In some other instances, the semiconductor device 100 can have two array regions 102 and a connection region 104 between the two array regions 102 along the X direction.

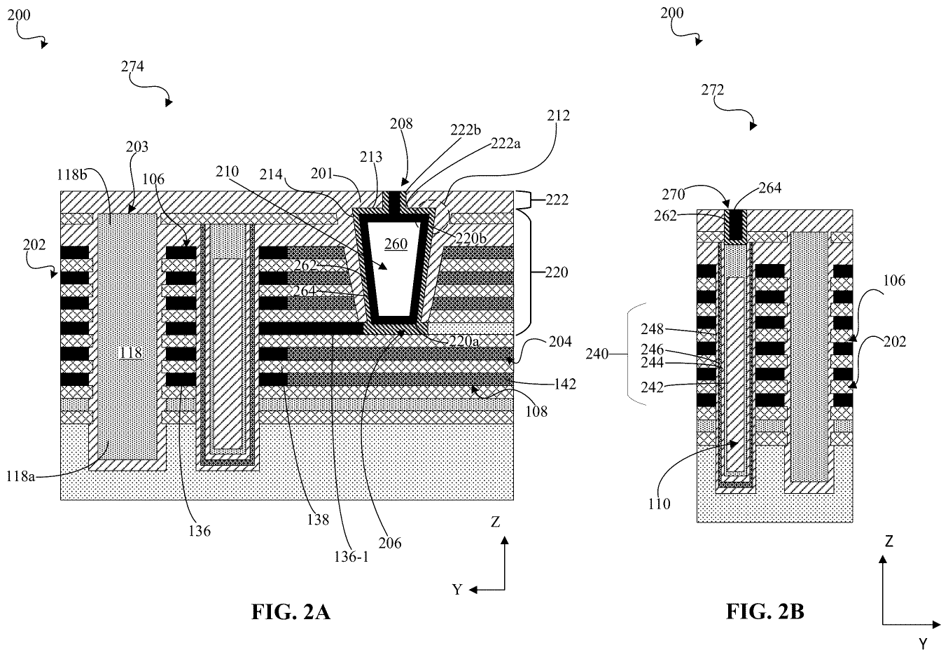

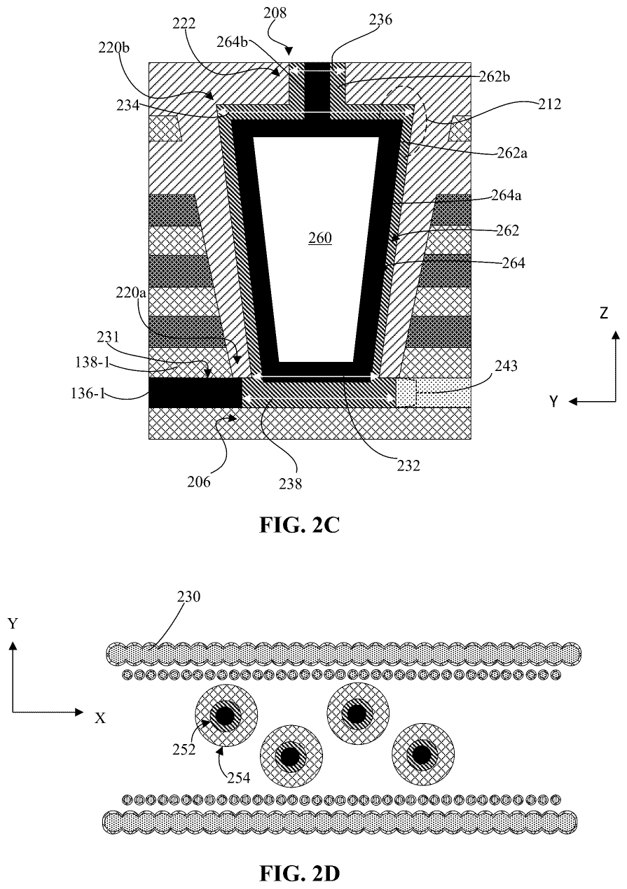

The semiconductor device 100 includes a first stack 106 of alternating conductive layers and isolation layers (e.g., conductive layers 136 and first dielectric layer 138 as shown in FIG. 2A). The conductive layers 136 can also be referred to as gate layers 136 in the present disclosure. In some implementations, a part of the first stack 106 can be in the array region 102, and another part of the first stack 106 can be in the connection region 104. The semiconductor device 100 further includes a second stack 108 of alternating dielectric layers and isolation layers (e.g., second dielectric layers 142 and first dielectric layer 138 as shown in FIG. 2A). In some implementations, the second stack 108 can be in the connection region 104. The first stack 106 is connected to the second stack 108. The part of the first stack 106 that is in the connection region 104 can also be referred to as the side connection stack 140 in this disclosure.

The semiconductor device 100 can include an array of channel structures 110 extending through the first stack 106. In some implementations, the array of channel structures 110 is in the array region 102. One or more channel structures 110 can be used to form a string of memory cells along a vertical direction (e.g., Z direction) perpendicular to the first horizontal direction. In some implementations, the semiconductor device 100 can include dummy channel structures 112 (also referred to as dummy memory strings) for process variation control during fabrication and/or for additional mechanical support. The dummy channel structures 112 can extend through the first stack 106. In some implementations, the dummy channel structures 112 are in the connection region 104. For example, some dummy channel structures 112 can be in an edge or peripheral area of the connection region 104. In some instances, the edge area of the connection region 104 is adjacent to the array region 102. In some other instances, the edge area of the connection region 104 is adjacent to a slit structure 118, e.g., in the side connection stack 140. In some implementations, the dummy channel structures 112 are in the array region 102 (e.g., in an area of the array region that is adjacent to the connection region 104).

The semiconductor device 100 can include one or more slit structures 118. Each slit structure 118 can extend in the X direction. The slit structure 118 can extend into both the array region 102 and the connection region 104. In some implementations, the slit structures 118 can divide an array region into multiple memory blocks. In some implementations, the slit structure 118 can function as a common source contact for the channel structures 110 in the array region 102. In some implementations, as shown in FIG. 1, each slit structure 118 can include multiple segments 116. In some implementations, the adjacent segments 116 are separated and spaced by isolation structures 111 along the X direction. The isolation structures 111 can eliminate or reduce stress built in the slit structure 118 during the manufacturing process, thereby preventing the slit structure 118 from bending or cracking. The isolation structure 111 can also be used to separately control the formation of openings between adjacent first dielectric layers in the array region 102 and connection region 104 for gate layer replacement.

In some implementations, as shown in FIG. 1, the isolation structure 111 is in the connection region 104 and is adjacent to the array region 102. In some other implementations, the isolation structure 111 is in the array region 102 and is adjacent to the connection region 104. In some other implementations, the isolation structure 111 can have a portion in the array region 102 and another portion in the connection region 104. In some implementations (not shown in FIG. 1), the slit structure 118 can further include one or more segments extending along a second horizontal direction (e.g., the Y direction). In some implementations, the slit structure 118 can include multiple segments connected in an H shape or a T shape. In some implementations, the segments 116 of each slit structure 118 can have similar or a same width (e.g., along the Y direction). In some other implementations, the segments 116 of each slit structure 118 can have different widths (e.g., along the Y direction). In some implementations, along the Y direction, a width of the segment 116 in the connection region 104 is larger than a width of the segment 116 in the array region 102. For example, the width of the segment 116 in the connection region 104 can be approximately 1.5 to 2 times that of the segment 116 in the array region 102.

In some implementations, slit structure 118 is an insulating structure that does not include any contact therein (e.g., not functioning as the source contact) and thus, does not introduce parasitic capacitance and leakage current with first conductive layers 136 (gate layers). In some implementations, slit structure 118 is a front-side source contact further including an inner conductive portion (e.g., including W, polysilicon, and/or TiN) circumscribed by a slit spacer.

In some implementations, as illustrated in FIG. 1, the semiconductor device 100 includes one or more contact structure 120 extending through the second stack 108 in the connection region 104. In some implementations, the contact structures 120 can extend vertically into the second stack structure 108 at different depths in the z-direction, according to some implementations. The top surfaces of different contact structures can be aligned with one another (e.g., from a chemical mechanical polishing (CMP) process), while the bottom surfaces of different contact structures 120 can extend to different levels to couple to different gate layers in the first stack 106. Therefore, the gate layers 136 in the first stack 106 can be coupled out to control circuits through corresponding contact structures 120.

FIG. 2A illustrates a cross-sectional view of a portion of an example connection region 274 of an example semiconductor device 200 including an example contact structure 210. FIG. 2B illustrates a cross-sectional view of a portion of an example array region 272 of the example semiconductor device 200. FIG. 2C is an enlarged view of a contact structure 210 in FIG. 2A. FIG. 2D illustrates a plan view of a portion of the example semiconductor device 200. For ease of description, reference will be made to FIGS. 2A-2D when describing the semiconductor device 200 and the contact structure 210.

The semiconductor device 200 can be, e.g., the semiconductor device 100 of FIG. 1. The array region 272 can be the array region 102 of FIG. 1. The connection region 274 can be the connection region 104 of FIG. 1. The semiconductor device 200 can include a memory array structure 202 including a first stack 106 of first dielectric layers 138 and conductive layers 136 alternating with each other along a first direction (e.g., z direction) and at least one channel structure 110 extending in the first stack 106 along z direction. As noted above, the channel structures 110 can be used to form memory cells (e.g., NAND memory cells).

In some implementations, as illustrated in FIG. 2A, the channel structure 110 includes a layered structure 240 comprises a blocking layer 248, a charge trapping layer 246 (also called storage layer in some cases), a dielectric layer 244 (also called a tunneling layer in some cases), and a semiconductor channel layer 242. The semiconductor channel layer 242 is in contact with and laterally surrounded by the dielectric layer 244. The dielectric layer 244 is in contact with and laterally surrounded by the charge trapping layer 246. The charge trapping layer 246 is in contact with and laterally surrounded by the blocking layer 248. In other words, the filling layer 512, semiconductor channel layer 242, dielectric layer 244, charge trapping layer 246, and blocking layer 248 can be arranged radially from the center toward the outer surface of the channel structure 510 in this order. The semiconductor channel layer 242 can include doped polysilicon or silicon germanium (SiGe). The dopants can be N type dopants (e.g., Phosphorus (P) or Arsenic (As)) or P type dopants (e.g., Boron (B) or Gallium (Ga)) at a desired doping level. Dielectric layer 244 may include silicon oxide, silicon oxynitride, or any combination thereof. Charge trapping layer 246 may include silicon nitride, silicon oxynitride, silicon, or any combination thereof. Blocking layer 248 may include silicon oxide, silicon oxynitride, high dielectric constant (high-k) dielectrics, or any combination thereof. In one example, the layered structure 240 can include silicon oxide/silicon oxynitride (or silicon nitride)/silicon oxide/polysilicon (ONOP), for the blocking layer 248, the charge trapping layer 246, the dielectric layer 244, and the semiconductor channel layer 242, respectively.

The semiconductor device 200 can further include a connection structure 204. The connection structure 204 can include a second stack 108 of the first dielectric layers 138 and second dielectric layers 142 alternating with each other along Z direction. The semiconductor device 200 can include a contact structure 210 extending at least partially in the connection structure along Z-direction. The contact structure 210 can be the contact structure 120 of FIG. 1. As noted above, the contact structure 210 can be used to couple a corresponding gate layer 136 to a control circuit.

In some implementations, as illustrated in FIGS. 2A and 2C, the contact structure 210 includes a first end 206, a second end 208 and a step structure 212 between the first end 206 and the second end 208 along Z direction. The first end 206 can be coupled to a corresponding conductive layer 136 of the first stack 106 of the memory array structure 202. For example, as illustrated in FIG. 2A, the first end 206 of the contact structure 210 can be electrically coupled to a first conductive layer 136-1 of the conductive layers of the first stack 106. The first end 206 of the contact structure 210 can also be referred to as a lower end 206 of the contact structure 210, and the second end 208 of the contact structure 210 can also be referred to as a upper end 208 of the contact structure 210 in the present disclosure.

In some implementations, the step structure 212 includes a first surface 213 and a second surface 214 intersecting with the first surface 213. In some implementations, the intersection line between the first surface 213 and the second surface 214 has a circle shape. As illustrated in FIG. 2A, the first surface 213 can extend along y direction and is between the upper end 208 and the lower end 206 along Z direction, and the second surface 214 can be in contact with the lower end 206. The first surface 213 can be a flat surface, while the second surface can be a curved surface (e.g., with a cylindrical shape). In some implementations, the first surface 213 is perpendicular to Z direction. In some implementations, the second surface 214 extends from the first surface 213 towards the lower end 206 of the contact structure 210 in a direction different from Y direction. In some implementations, the direction along which the second surface 214 extends is not perfectly aligned with the Z direction but tilted with an angle relative to the Z direction. For example, as shown in FIG. 2A, a cross-sectional view of a combination of the second surface 214 and the first surface 213 can have a trapezoid shape.

In some implementations, the contact structure 210 includes a first portion 220 and a second portion 222. The first portion 220 can include a first end 220a and a second end 220b opposite to the first end 220a along Z direction. Similarly, the second portion 222 can include a first end 222a and a second end 222b. As shown in FIG. 2A, the second end 220b of the first portion 220 is coupled to the first end 222a of second portion 222. The first end 220a of the first portion 220 of the contact structure 210 can be the same as or similar to the lower end 206 of the contact structure 210, and the second end 222b of the second portion 222 of the contact structure 210 can be the same as or similar to the upper end 208 of the contact structure 210.

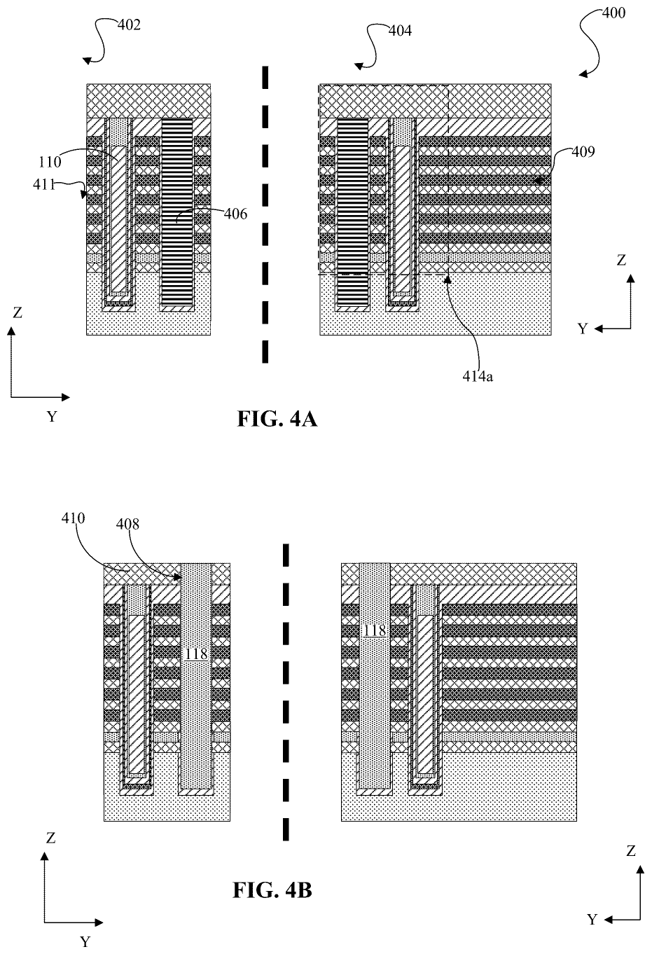

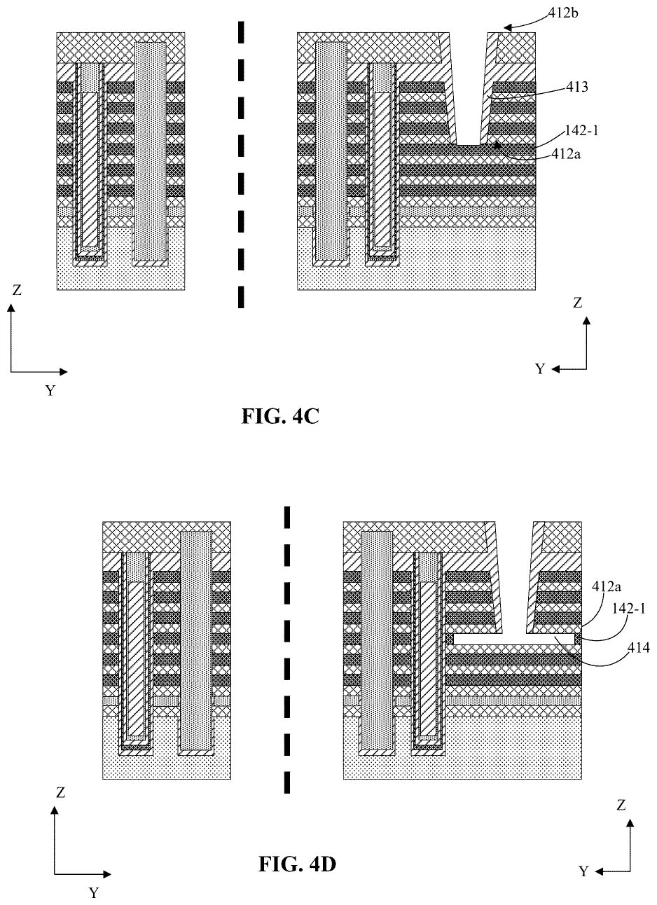

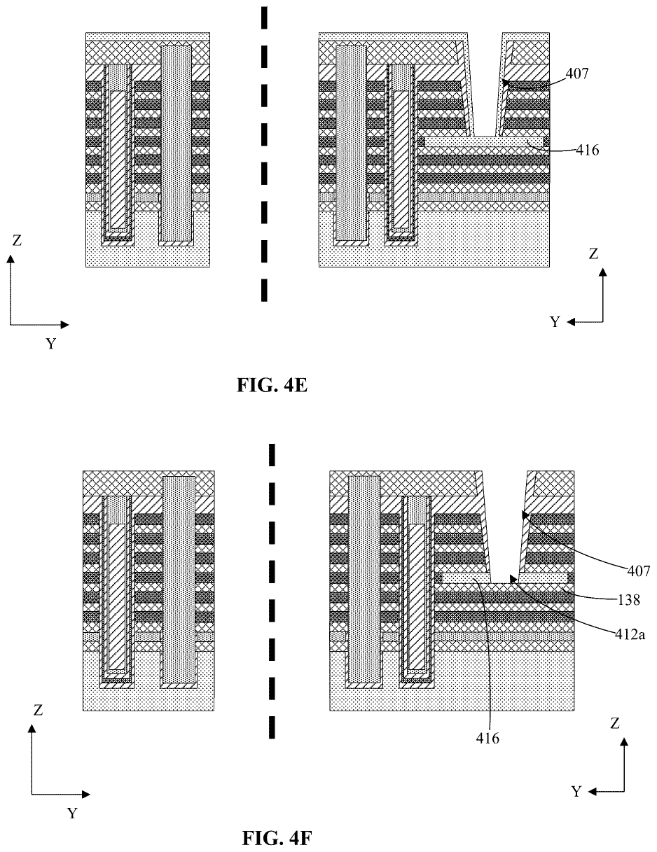

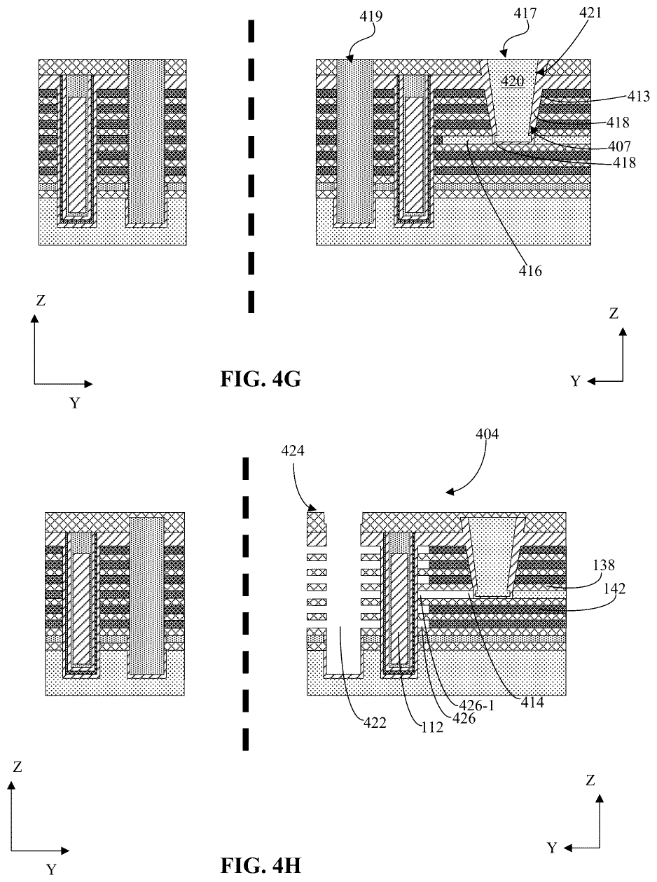

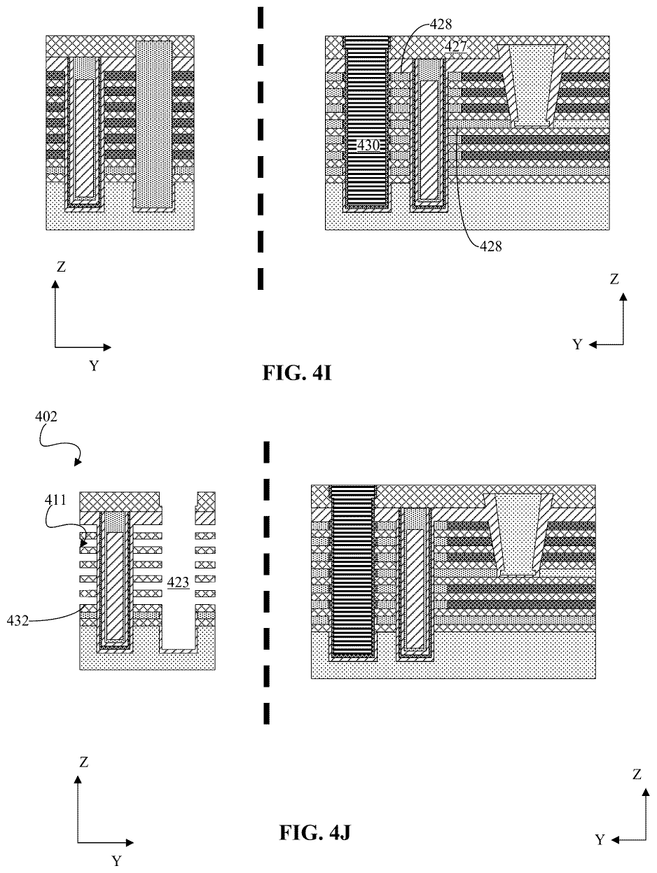

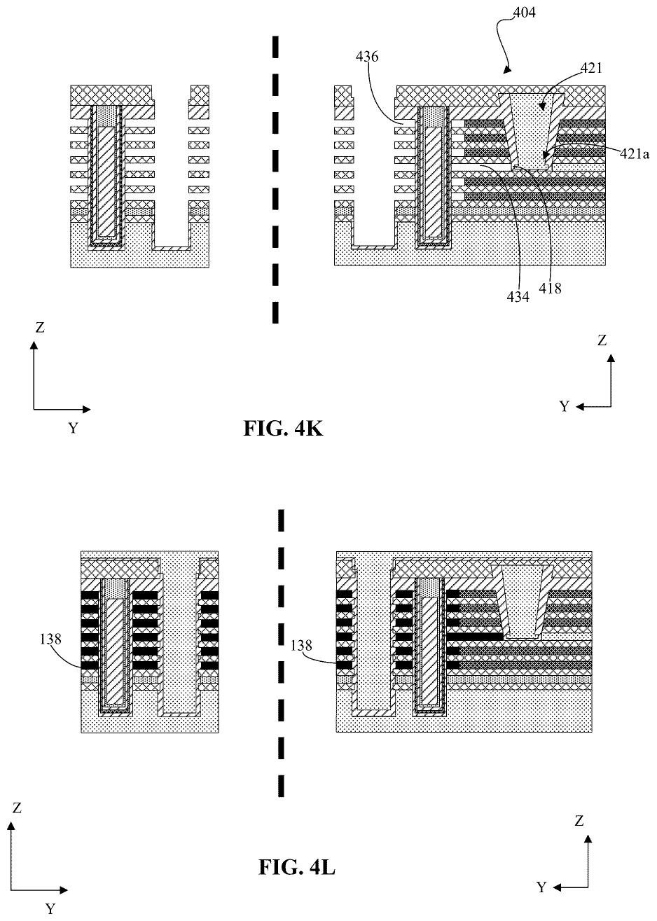

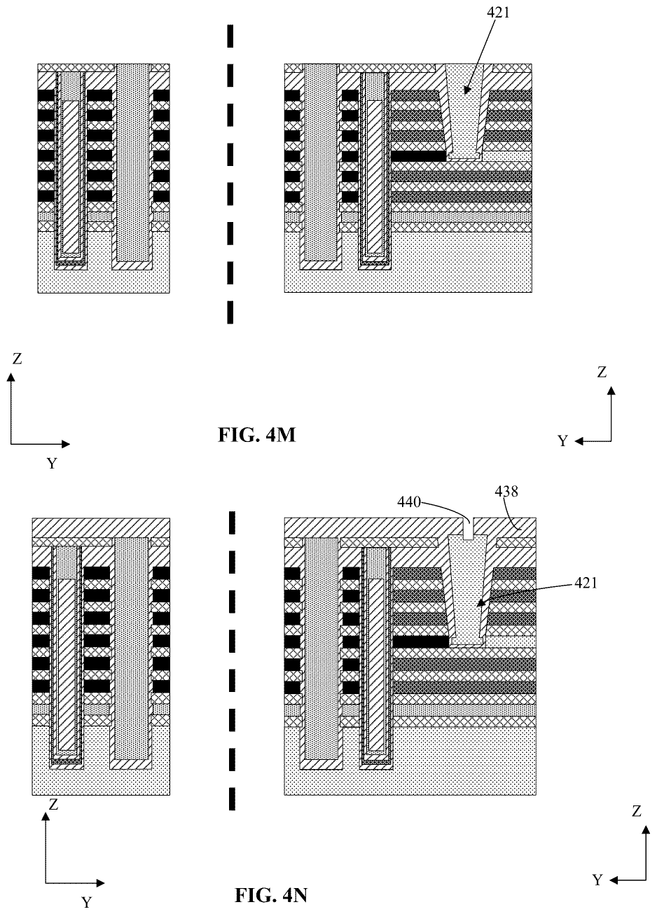

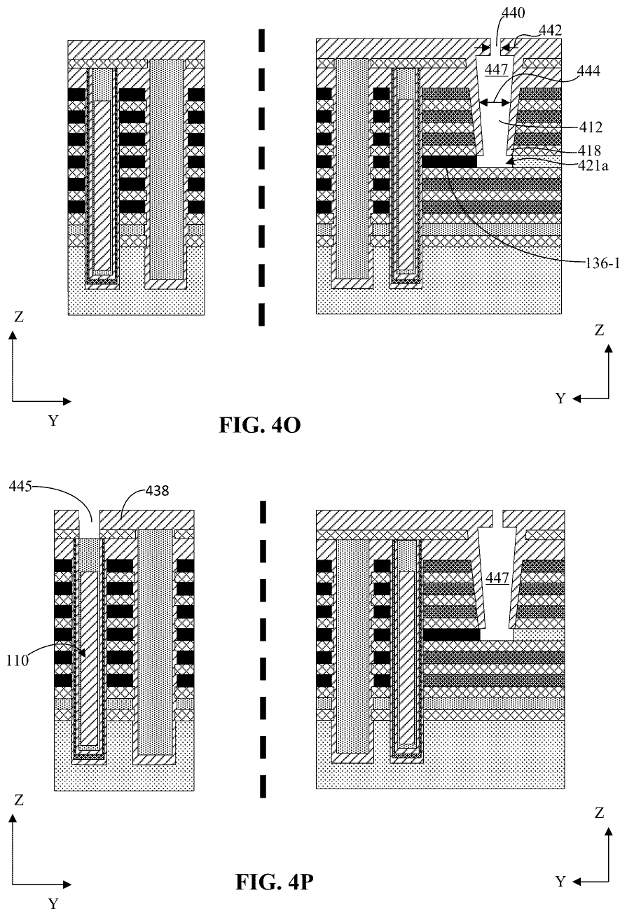

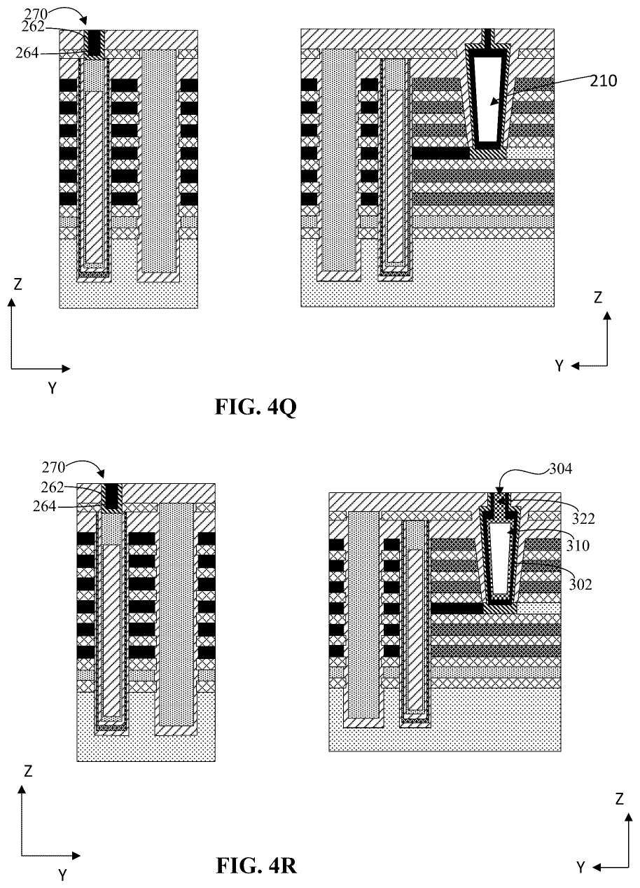

As shown in FIG. 2C, in some implementations, a size 232 of the first end 220a of the first portion 220 along Y direction is smaller than a size 234 of the second end 220b of the first portion 220 along the same direction, and the size 234 of the second end 220b of the first portion 220 is greater than a size 236 of the second portion 222 along Y direction. In some implementations, the size 232 of the first end 220a of the first portion 220 refers to a minimum width of the first end 220a of the first portion 220 along Y direction. For example, as illustrated in FIG. 2C, the first end 220a of the first portion 220 of the contact structure 210 can include a bottom part 243 that is at the same level with the first conductive layer 136-1 and in contact with the first conductive layer 136-1. As described in further details below in reference to FIGS. 4A-4R, the bottom part 243 can be formed by replacing a portion of the second dielectric layer 142 with at least one conductive material. The bottom part 243 can have a width 238 along Y direction. The width 238 of the bottom part 243 can be greater than the width 232 that is at the interface 231 between a neighboring first dielectric layer 138-1 and the first conductive layer 136-1. Therefore, when the size of the first end 220a of the first portion 220 refers to a minimum width of the first end 220a of the first portion 220 along Y direction, in the present example of FIG. 2C, the size 232 can be representative of the size of the first end 220a of the first portion 220 of the contact structure 210.

With continued reference to FIG. 2C, in some implementations, a size 236 of the upper end 208 is smaller than an outer size 234 of the step structure 212. The size 236 of the upper end 208 can refer to an average size of the upper end 208 or a minimum size of the upper end 208. The outer size 234 of the step structure 212 can refer to the size of the second end 220b of the first portion 220. In other words, the second portion 222 of the contact structure 210 can have a smaller size than the first portion 220 of the contact structure 210. In some implementations, the size 236 of the second portion 222 of the contact structure 210 is between 50 nm and 300 nm, while the outer size 234 of the step structure 212 of the contact structure 210 is in a range between 500 nm and 1800 nm.

In some implementations, the outer size 234 of the step structure 212 along Y direction is greater than a size 232 of the lower end 206 along the same direction. In other words, a cross-sectional view of the contact structure 210 in Y-Z plane can have a trapezoid shape with a smaller end in the negative Z direction and a bigger end in the positive Z direction. In some implementations, the size 232 of the lower end 206 is about 70% of the outer size 234 of the step structure 212. In some implementations, the size 236 of the upper end 208 is smaller than the size 232 of the lower end 206 along Y direction.

As illustrated in FIG. 2A, the semiconductor device 200 includes a slit structure 118 extending along Z direction. The slit structure 118 can be the slit structure 118 in FIG. 1 or any segment 116 of the slit structure 118 in FIG. 1. The slit structure 118 includes a first end 118a and a second end 118b opposite to the first end 118a along Z direction. In some implementations, a surface 203 of the second end 118b of the slit structure 118 is aligned with the first surface 213 of the step structure 212 of the contact structure 210. For example, the surface 203 of the slit structure 118 and the first surface 213 of the contact structure 210 can be substantially at a same level along Z direction (e.g., with a difference less than or equal to 20 nm along Z direction), or substantially lie in the same plane.

In some implementations, as illustrated in FIG. 2C, the contact structure 210 includes at least one conductive structure and an air gap 260. The at least one conductive structure can include a first conductive structure 262 and a second conductive structure 264. The at least one conductive structure can be formed on sidewalls of the contact structure 210. The second conductive structure 264 can be between the first conductive structure 262 and the air gap 260. In some implementations, the first portion 220 of the contact structure 210 includes a first part 262a of the first conductive structure 262, a first part 264a of the second conductive structure 264, and the air gap 260. The second portion 222 of the contact structure 210 includes a second part 262b of the first conductive structure 262 and a second part 264b of the second conductive structure 264. In the second portion 222 of the contact structure 210, the second part 264b of the second conductive structure 264 can be at least partially surrounded (e.g., laterally surrounded) by the second part 262b of the first conductive structure 262. In some implementations, the second portion 222 of the contact structure 210 are substantially filled with the first conductive structure 262 and the second conductive structure 264 without air gap, as illustrated in FIG. 2A.

In some implementations, with continued reference to FIG. 2C, in the second portion 222 of the contact structure 210, both the second part 264b of the second conductive structure 264 and the second part 262b of the first conductive structure 262 extend along Z direction. The first part 264a of the second conductive structure 264 are in direct contact with the second part 264b of the second conductive structure 264. Therefore, there can be no first conductive structure 262 and/or other layers between the first part 264a of the second conductive structure 264 and the second part 264b of the second conductive structure 264. In some implementations, the first conductive structure 262 includes titanium nitride (TiN) or tantalum nitride (TaN), and the second conductive structure 264 includes tungsten (W). In some implementations, the first conductive structure 262 has a thickness in a range between 15 nm to 30 nm, and the second conduct structure 264 has a thickness in a range between 75 nm to 125 nm.

In some implementations, as illustrated in FIG. 2D, in a plane where the first surface 213 extends (e.g., in the X-Y plane), a cross-section of the upper end 208 of the contact structure 210 is a first circle 252. A cross-section of the step structure 212 of the contact structure 210 is a second circle 254. The first circle 252 and the second circle 254 can be substantially concentric. A diameter of the first circle 252 can be smaller than a diameter of the second circle 254. It is understood that the example in FIG. 2A is for illustration purpose and is not intended to be construed in a limiting sense. The cross-section of the contact structure 210 can have any suitable shapes.

As illustrated in FIG. 2B, the semiconductor device 200 includes a channel contact 270 coupled to the channel structure 110. The channel contact 270 can couple the channel structure 110 to a bit line. In some implementations, a conductive material of the channel contact 270 is same as a conductive material of the contact structure 210. For example, the channel contact 270 can include at least one conductive structure (e.g., the first conductive structure 262 and the second conductive structure 264), which have the same material as the contact structure 210 in FIG. 2A. As described below in reference to FIGS. 4A-4R, the conductive structures can be deposited in the channel contact opening and the contact structure opening at the same process steps.

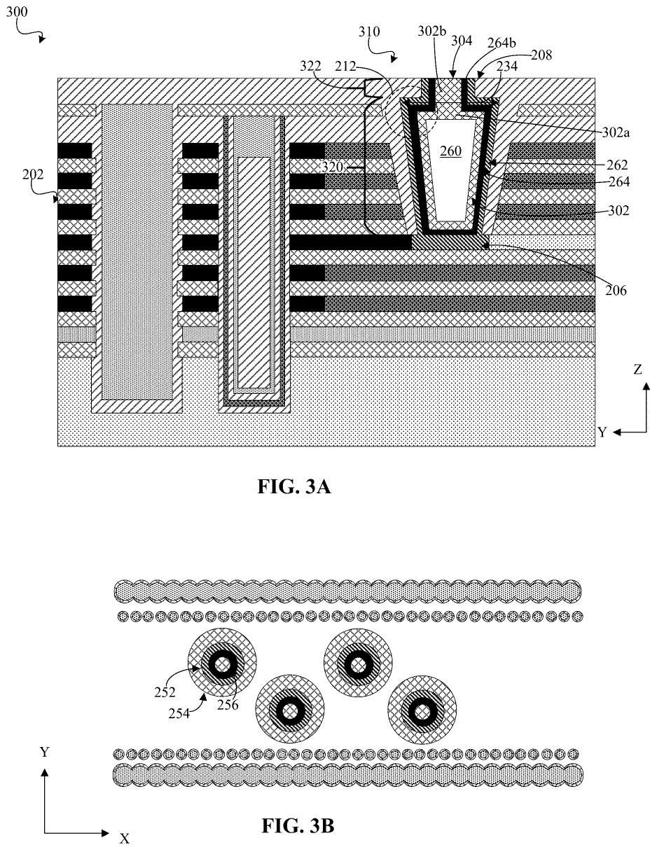

FIG. 3A illustrates a cross-sectional view of a portion of another example semiconductor device 300 including another example contact structure 310. FIG. 3B illustrates a plan view of a portion of the example semiconductor device 300. For ease of description, reference will be made to FIGS. 3A and 3B when describing the semiconductor device 300 and the example contact structure 310. The semiconductor device 300 differs from the semiconductor device 200 primarily in the contact structure. Additional description of the same structures in both semiconductor devices 200, 300 will be omitted to avoid redundancy.

As illustrated in FIG. 3A, similar to or same as the contact structure 210 of the semiconductor device 200, the contact structure 310 includes at least one conductive structure and an air gap 260. The at least one conducive structure can include the first conductive structure 262 and the second conductive structure 264. In some implementations, unlike the contact structure 210 of the semiconductor device 200, the contact structure 310 includes a dielectric layer 302 between the air gap 260 and the second conductive structure 264. The dielectric layer 302 can include, but not limited to, silicon oxide, silicon nitride, silicon oxynitride, or any combination thereof.

In some implementations, the dielectric layer includes a first part 302a in the first portion 320 of the contact structure 310 and a second part 302b in the second portion 322 of the contact structure 310. The first part 302a of the dielectric layer 302 is in contact with the second part 302b of the dielectric layer 302, as illustrated in FIG. 3A.

In some implementations, unlike the contact structure 210 of FIG. 2A, the upper end 208 of the contact structure 310 includes the second part 302b of the dielectric layer 302 that is at least partially surrounded by the second part 264b of the second conductive structure 264. In some implementations, the second part 302b of the dielectric layer 302 has no air gap or air seam. In some implementations, as described below in reference to FIG. 4R, the dielectric layer 302 is filled using the atomic layer deposition (ALD) process. Compared to other deposition processes (e.g., chemical vapor deposition (CVD), or physical vapor deposition (PVD)), ALD may effectively prevent the formation of air gaps or seams in the second portion 322 of the contact structure 310 and/or close to a top surface 304 of the contact structure 310. This can help to avoid exposing air gaps or seams during subsequent chemical mechanical polishing (CMP) processes, thus preventing the internal structure of the contact structure 310 from being exposed.

Similar to or same as the contact structure 210 of FIG. 2A, the contact structure 310 has a lower end 206, an upper end 208 and a step structure 212. In some implementations, a size of the upper end 208 of the contact structure 310 is between 300 nm and 500 nm. In some implementations, an outer size 234 of the step structure 212 of the contact structure 310 is between 500 nm and 1800 nm.

As illustrated in FIG. 3B, in X-Y plane, a cross-section of the upper end 208 of the contact structure 310 is a first circle 252. A cross-section of the step structure 212 of the contact structure 310 is a second circle 254. A cross-section of the dielectric layer 302 in the second portion 322 of the contact structure 310 is a third circle 256. The first circle 252, the second circle 254 and the third circle 256 can be substantially concentric. A diameter of the first circle 252 can be smaller than a diameter of the second circle 254. It is understood that the example in FIG. 3A is for illustration purpose and is not intended to be construed in a limiting sense. The cross-section of the contact structure 310 can have any suitable shapes.

FIGS. 4A-4R illustrate cross-sectional views of an example semiconductor device 400 at various steps of a manufacturing process. Each figure includes a cross-sectional view for a connection region 404 and a cross-sectional view for an array region 402. The semiconductor device 400 can be, e.g., the semiconductor device 200 of FIGS. 2A-2D, or the semiconductor device 300 of FIGS. 3A and 3B. The connection region 404 can be, e.g., the connection region 104 of FIG. 1, or the connection region 274 of FIGS. 2A-3B. The array region 402 can be, e.g., the array region 102 of FIG. 1, or the array region 272 of FIGS. 2A-3B.

As illustrated in FIG. 4A, an initial array structure 411 and an initial connection structure 409 are formed. The initial array structure 411 and the initial connection structure 409 can include interleaved first dielectric layers 138 and second dielectric layers 142. The first dielectric layers 138 and the second dielectric layers 142 can be made of materials including, but not limited to, silicon oxide, silicon nitride, silicon oxynitride, or any combination thereof. The first dielectric layers 138 can have different materials from the second dielectric layers 142. In some implementations, the first dielectric layers 138 include silicon oxide, and the second dielectric layers 142 include silicon nitride. As described with further details below, the initial array structure 411 and an edge region 414a of the initial connection structure 409 can form the first stack structure 106. The remaining region of the initial connection structure 409 can form the second stack structure 108.

The channel structures 110 can be formed in the initial array structure 411 extending along Z direction. An initial slit structure 406 can be formed in the initial array structure 411 and initial connection structure 409. In some implementations, the initial slit structure 406 has the same width, pitch, or height as the channel structures 110. In some implementations, the initial slit structure 406 includes a first sacrificial material, e.g., carbon.

As illustrated in FIG. 4B, the slit structure 118 is formed, which extends further into a first interlayer dielectric (ILD) 410 that is deposited above the initial array structure 411 and the initial connection structure 409. Although not shown in FIG. 4B, forming the slit structure 118 from the initial slit structure 406 can include multiple process steps. For example, an opening 408 can be formed extending through the first ILD 410 to expose the initial slit structure 406. Through the opening 408, the first sacrificial material inside the initial slit structure 406 can be removed to form holes. The holes can further be expanded laterally (e.g., along X and Y direction) to form a slit structure hole extending through both the first ILD 410 and the initial array structure 411. The slit structure hole can be subsequently filled with a supporting material, e.g., polysilicon. Therefore, compared to the initial slit structure 406 shown in FIG. 4A, the slit structure 118 in FIG. 4B can have a different material, a greater height along Z direction and/or a greater width along X and Y direction. It is to be understood that FIGS. 4A-4R are not necessarily drawn to scale. Although the slit structure 118 in FIG. 4B appears to have a similar width as the initial slit structure 406 in FIG. 4A, in a real device, the slit structure 118 can be wider than the initial slit structure 406.

The process steps described above can involve multiple etch processes. In some implementations, etching involves one or more dry etching and/or wet etching techniques, including, but not limited to, reactive ion etching (RIE), plasma etching, hydrofluoric acid (HF) etching, sputtering etching, KOH Etching (Potassium Hydroxide), TMAH Etching (Tetramethylammonium Hydroxide), Buffered Oxide Etchant (BOE), Piranha Solution (H₂SO₄/H₂O₂), or any combination thereof. The supporting material can be deposited using one or more thin film deposition techniques, including, but not limited to, chemical vapor deposition (CVD), physical vapor deposition (PVD), plasma enhanced chemical vapor deposition (PECVD) atomic layer deposition (ALD), sputtering, or any combination thereof.

As illustrated in FIG. 4C, an initial contact structure opening 412 can be formed, which extends into the initial connection structure 409 and lands on a corresponding second dielectric layer 142-1. The initial contact structure opening 412 can be also referred to as a first portion of a contact structure opening in the present disclosure. The initial contact structure opening 412 can be used to form the first portion of the contact structure (e.g., first portion 220 of the contact structure 210 of FIG. 2A, or first portion 320 of the contact structure 310 of FIG. 3A) at later stages. Due to the etching process, the initial contact structure opening 412 can have a wider upper end 412b and a narrower lower end 412a. The etching process can use the etching techniques described above. In some implementations, a spacer layer 413 is deposited inside the initial contact structure opening 412. The spacer layer 413 can include dielectric materials including, but not limited to, silicon oxide, silicon nitride, silicon oxynitride, or any combination thereof.

As illustrated in FIG. 4D, a disk opening 414 can be formed by removing a part of the corresponding second dielectric layer 142-1 that is in contact with the lower end 412a of the initial contact structure opening 412. The disk opening 414 can have a greater width along Y direction compared to the lower end 412a of the initial contact structure opening 412. In some implementations, the disk opening 414 is formed by introducing wet etchants through the initial contact structure opening 412. In some implementations, the wet etchant includes phosphoric acid (H₃PO₄). It is to be noted the word “disk” in the disk opening 414 is not to be construed in a limiting sense. The disk opening 414 can have any regular or irregular shape in X-Y plane.

As illustrated in FIG. 4E, a first liner 416 can be deposited into the disk opening 414 and on sidewalls 407 of the initial contact structure opening 412. In some implementations, the first liner 416 includes polysilicon. The first liner 416 can be deposited by one or more thin film deposition techniques, including, but not limited to, chemical vapor deposition (CVD), physical vapor deposition (PVD), atomic layer deposition (ALD), Metal-Organic Chemical Vapor Deposition (MOCVD), sputtering, electroplating, electroless plating, electron-beam evaporation, or any combination thereof.

As illustrated in FIG. 4F, a part of first liner 416 can be removed from the sidewalls 407 and the lower end 412a of the initial contact structure opening 412, which at least partially exposes the underlying first dielectric layer 138. The removal process can involve dry etch or wet etch techniques described above. In some implementations, the removal process involves a wet etching using Tetramethylammonium hydroxide (TMAH).

As illustrated in FIG. 4G. a second liner 418 can be formed on sidewalls 407 and lower end 412a of the initial contact structure opening 412. The second liner 418 can include a dielectric material including, but not limited to, silicon oxide, silicon nitride, silicon oxynitride, or any combination thereof. In some implementations, the second liner 418 has the same material has the spacer layer 413. In some implementations, the second liner 418 includes silicon oxide. A sacrificial structure 420 can be subsequently deposited into the initial contact structure opening 412. In some implementations, the sacrificial structure 420 includes polysilicon. The sacrificial structure 420 can be separated from the first liner 416 in the disk opening 414 by the second liner 418 at the lower end 412a of the initial contact structure opening 412. The initial contact structure opening 412 that is filled with the second liner 418 and the sacrificial structure 420 can be referred to as an initial contact structure 421 in the present disclosure.

With continued reference to FIG. 4G, a CMP process can be performed to remove extra sacrificial structure material formed outside the initial contact structure 421 during the deposition process. In some implementations, the CMP process also removes away a part of an upper end of the initial contact structure 421 and/or a part of an upper end of the slit structure 118, which substantially aligns a top surface 417 of the initial contact structure 421 with a top surface 419 of the slit structure 118 (e.g., with a difference less than or equal to 20 nm along Z direction).

As illustrated in FIG. 4H, the material inside a segment of the slit structure 118 can be removed. As noted above in reference to FIG. 1, the slit structure 118 can include multiple segments 116. At the process step illustrated in FIG. 4H, the segment of the slit structure 118 that is located in the connection region 404 can be utilized (e.g., the segment 116a as illustrated in FIG. 1). By removing the material inside the segment 116a of the slit structure 118, a segment opening 422 can be formed, exposing edges of the second dielectric layers 142. The segment opening 422 can provide an access point for introducing etchants to etch away a part of the second dielectric layers 142 near the segment opening 422, forming side connection openings 426 between adjacent first dielectric layers 138, as illustrated in FIG. 4H. As noted above in reference to FIG. 1, the dummy channel structure 112 can provide mechanical support to the stack structure and prevent it from collapsing. In some implementations, the side connection openings 426 extend beyond at least one dummy channel structure 112 along Y direction, and a corresponding side connection opening (e.g., the one that is on the same level as the disk opening 414) reaches the first liner 416 inside the disk opening 414. For ease of description, the corresponding side connection opening that is on the same level as the disk opening 414 can be referred to as a first side connection opening 426-1 in the present disclosure.

Subsequently, through the first side connection opening 426-1, the first liner 416 inside the disk opening 414 can be removed by etching. The etchants used to remove the first liner 416 (e.g., polysilicon) can be different from the etchants used to remove second dielectric layers 142 for forming side connection openings 426. In some implementations, the etchant used at the process step shown in FIG. 4H has high selectivity for the polysilicon over the first dielectric layer 138 (e.g., silicon oxide) and second dielectric layer 142 (e.g., silicon nitride). Therefore, only the first liner 416 can be removed during etching without attacking or substantially attacking both first dielectric layers 138 and second dielectric layers 142.

As illustrated in FIG. 4I, a first temporary filler 428 can be deposited into the side connection openings 426 and the disk opening 414. A second temporary filler 430 can be formed inside the segment opening 422. The first temporary filler 428 can include polysilicon, and the second temporary filler 430 can include carbon. The first temporary filler 428 and the second temporary filler 430 can be formed using the deposition techniques described above. In some implementations, a CMP process is performed to remove extra filler materials above the ILD layer 427.

As illustrated in FIG. 4J, similar to the process step in connection with FIG. 4H, the second dielectric layers 142 in the array region 402 can be removed through an opening in the slit structure 118. However, unlike the process step in connection with FIG. 4H, a different segment of the slit structure 118 can be used at the present process step, for example, the segment 116b of the slit structure 118 that is located in the array region 102, as illustrated in FIG. 1. Additionally, unlike the process step in connection with FIG. 4H where the second dielectric layers 142 are only partially removed around the segment opening 422, here, in the initial array structure 411, the second dielectric layers 142 can be entirely or substantially entirely removed to form first openings 432 between adjacent first dielectric layers 138. This process can involve a longer etch time compared to that of the process to form side connection openings 426 in connection with FIG. 4H.

As illustrated in FIG. 4K, the first temporary filler 428 can be removed to form second openings 436 between adjacent first dielectric layers 138 in the connection region 404. The second openings 436 can include the side connection openings 426 and a part of the disk opening 414. For ease of description, a combination of the part of the disk opening 414 and the first side connection opening 426-1 can be referred to as a connection line opening 434 in the present disclosure. The connection line opening 434 can expose a part of the second liner 418 at the lower end 421a of the initial contact structure 421.

As illustrated in FIG. 4L, at least one conductive material can be deposited in the first openings 432 and the second openings 436 to form the conductive layers 136. The conductive layers 136 can be made of at least one conductive material including, but not limited to W, Co, Cu, Al, TiN, TaN, polysilicon, silicide, or any combination thereof. In some implementations, each conductive layer 136 includes multiple layers, such as a W layer over a TiN layer. The conductive layers 136 can be deposited by one or more thin film deposition processes including, but not limited to, chemical vapor deposition (CVD), physical vapor deposition (PVD), atomic layer deposition (ALD), Metal-Organic Chemical Vapor Deposition (MOCVD), sputtering, electroplating, electroless plating, electron-beam evaporation, or any combination thereof. Subsequently, a slit material can be deposited into the segment opening (e.g., the segment opening 423 of FIG. 4J). In some implementations, the slit material includes polysilicon.

As illustrated in FIG. 4M, the extra slit material outside the slit structure 118 can be removed. In some implementations, the ILD 427 that is above the initial contact structure 421 is also removed. The removing process can include etching and/or polishing. After removal of both the extra slit material and the ILD 427, the upper end of the initial contact structure 421 can be exposed.

As illustrated in FIG. 4N, another ILD layer 438 can be deposited on the initial contact structure 421. An upper opening 440 can be formed extending through the ILD layer 438 and exposing a part of the initial contact structure 421. The upper opening 440 can also be referred to as a second portion of the contact structure opening in the present disclosure. The upper opening 440 can be used to form the second portion of the contact structure at later stages (e.g., the second portion 222 of the contact structure 210 of FIG. 2A, or the second portion 322 of the contact structure 310 of FIG. 3A).

As illustrated in FIG. 4O, the sacrificial structure 420 in the initial contact structure 421 can be moved. The upper opening 440 and the initial contact structure opening 412 can form a contact structure opening 447. A part of the second liner 418 that is located in the lower end 421a of the initial contact structure 421 can also be removed, exposing the first conductive layer 136-1 inside the connection line opening 434. The first conductive layer 136-1 inside the connection line opening 434 can be referred as a connection line in the present disclosure.

In some implementations, with continued reference to FIG. 4O, a size 444 of the first portion of the contact structure opening 447 (e.g., the initial contact structure opening 412) along Y direction is greater than a size 442 of the second portion of the contact structure opening 447 (e.g., the upper opening 440) along the same direction. The size 444 of the first portion of the contact structure opening 447 can be an average width or diameter of the first portion, while the size 442 of the second portion of the contact structure opening 447 can be an average width or diameter of the second potion.

As illustrated in FIG. 4P, a channel contact opening 445 can be formed, which extends at least through the ILD layer 438 to expose an upper end of the channel structure 110. The channel contact opening 445 can be formed by etching techniques described above.

FIG. 4Q are identical to FIGS. 2A and 2B. As illustrated in FIG. 4Q, the channel contact 270 and the contact structure 210 can be formed together, e.g., by depositing the first conductive structure 262 and the second conductive structure 264 into both the channel contact opening 445 and the contact structure opening 447. Specifically, the first conductive structure 262 and the second conductive structure 264 can be deposited in the contact structure opening 447 through the upper opening 440 of the contact structure opening 447. Therefore, a conductive material of the channel contact 270 can be the same as a conductive material of the contact structure 210. In some implementations, the first conductive structure 262 is deposited by atomic layer deposition (ALD). In some implementations, the first conductive structure 262 includes titanium nitride (TiN) or tantalum nitride (TaN), and the second conductive structure 264 includes tungsten (W). In some implementations, a CMP process is performed to remove conductive materials formed outside the channel contact 270 and the contact structure 210 during the deposition process.

By forming the channel contact 270 and the contact structure 210 together, both the manufacturing costs and process complexity can be significantly reduced. Combining these steps reduces the need for separate processes, which would otherwise require additional materials, time, and equipment. The technologies streamline the manufacture flow, allowing for faster production cycles. Moreover, fewer process steps may reduce the likelihood of errors or defects, leading to higher yield.

FIG. 4R is similar to FIG. 3A. It is to be noted that the contact structure 310 shown in FIG. 4R is an alternative embodiment of the contact structure 210 shown in FIG. 4Q. As illustrated in FIG. 4R, a dielectric layer 302 can be deposited into the contact structure opening 447 after depositing the first conductive structure 262 and the second conductive structure 264. As noted above, the dielectric layer 302 can be filled using the atomic layer deposition (ALD) process. Compared to other deposition processes (e.g., chemical vapor deposition (CVD), or physical vapor deposition (PVD)), ALD may effectively prevent the formation of air gaps or seams in the second portion 322 of the contact structure 310 and/or close to a top surface 304 of the contact structure 310. This can help to avoid exposing air gaps or seams during subsequent chemical mechanical polishing (CMP) processes, thus preventing the internal structure of the contact structure 310 from being exposed.

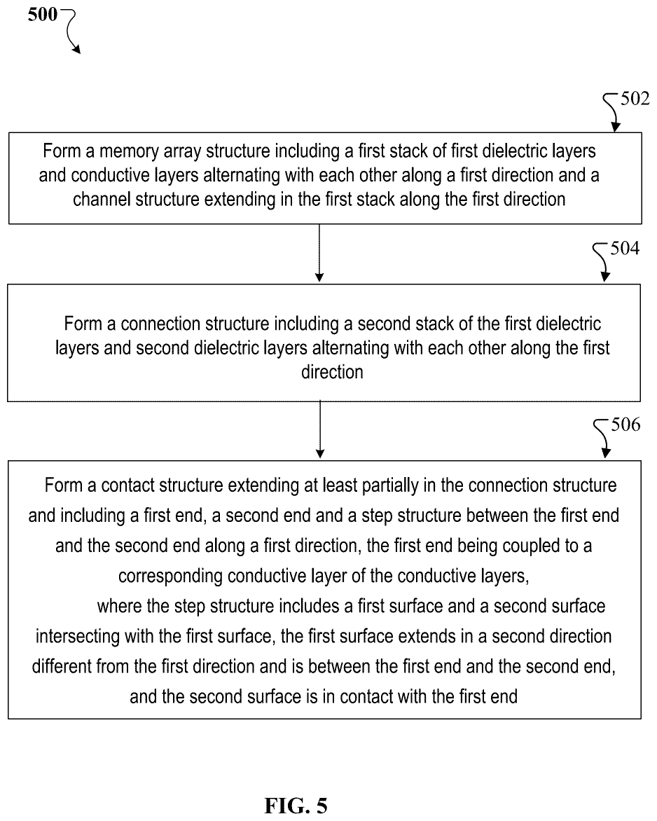

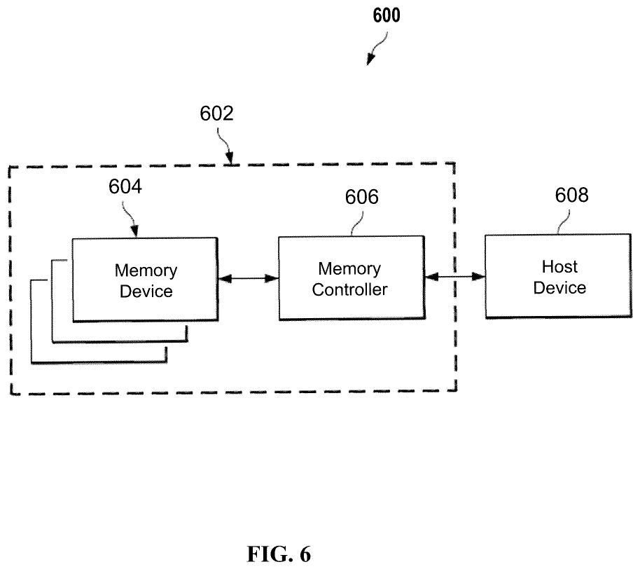

FIG. 5 is a flow chart of an example process 500 of a method of forming an example semiconductor device. The example semiconductor device can be, e.g., the semiconductor device 100 of FIG. 1, the semiconductor device 200 of FIGS. 2A-2D, the semiconductor device 300 of FIGS. 3A and 3B, or the semiconductor device 400 of FIGS. 4A-4R.

At step 502, a memory array structure is formed. The memory array structure includes a first stack of first dielectric layers and conductive layers alternating with each other along a first direction and a channel structure extending in the first stack along the first direction. The memory array structure can be, e.g., the memory array structure 202 of FIGS. 2A, 2B, 3A and 4Q-4R. The first stack can be, e.g., the first stack 106 of FIGS. 2A, 2B, 3A and 4Q-4R. The first dielectric layers can be, e.g., the first dielectric layers 138 of FIGS. 2A-2C, 3A and 4A-4R. The conductive layers can be, e.g., the conductive layers 136 of FIGS. 2A-2C, 3A and 4L-4R. The channel structure can be, e.g., the channel structure 110 of any one of FIGS. 1, 2A, 2B, 3A and 4A-4R.

At step 504, a connection structure is formed. The connection structure includes a second stack of the first dielectric layers and second dielectric layers alternating with each other along the first direction. The connection structure can be, e.g., the connection structure 204 of FIGS. 2A, 2C, 3A and 4L-4R. The second stack can be, e.g., the second stack 108 of FIGS. 2A, 2C, 3A and 4L-4R. The second dielectric layers can be, e.g., the second dielectric layers 142 of FIGS. 2A, 2C, 3A and 4A-4R.

At step 508, a contact structure is formed. The contact structure extends at least partially in the connection structure and includes a first end, a second end and a step structure between the first end and the second end along a first direction. The first end is coupled to a corresponding conductive layer of the conductive layers. The step structure includes a first surface and a second surface intersecting with the first surface. The first surface extends in a second direction different from the first direction and is between the first end and the second end, and the second surface is in contact with the first end. The contact structure can be, e.g., the contact structure 120 of FIG. 1, the contact structure 210 of FIGS. 2A-2D and 4Q, or the contact structure 310 of FIGS. 3A, 3B and 4R. The first end can be, e.g., the lower end 206 of any one of FIGS. 2A, 2C, 3A and 4Q-4R. The second end can be, e.g., the upper end 208 of any one of FIGS. 2A, 2C, 3A and 4Q-4R. The step structure can be, e.g., the step structure 212 of any one of FIGS. 2A, 2C, 3A and 4Q-4R. The first surface can be, e.g., the first surface 213 of any one of FIGS. 2A, 2C, 3A and 4Q-4R. The second surface can be, e.g., the second surface 214 of any one of FIGS. 2A, 2C, 3A and 4Q-4R.

In some implementations, a channel contact is formed. The channel contact extends in a dielectric interlayer on the memory array structure. The channel contact is coupled to the channel structure, and a conductive material of the channel contact is same as a conductive material of the contact structure. The channel contact can be, e.g., the channel contact 270 of FIGS. 2A, 4Q and 4R. The dielectric interlayer can be, e.g., the ILD 438 of FIGS. 2A and 4P-4R.

In some implementations, a contact structure opening is formed extending in the connection structure. A channel contact opening is formed extending in the dielectric interlayer. A first conductive structure is deposited in both the contact structure opening and the channel contact opening. The contact structure opening can be, e.g., the contact structure opening 447 of FIGS. 4O and 4P. The channel contact opening can be, e.g., the channel contact opening 445 of FIG. 4P. The first conductive structure can be, e.g., the first conductive structure 262 of FIGS. 2A, 2C-3B and 4Q-4R.

In some implementations, forming the contact structure opening includes: forming a first portion of the contact structure opening extending in the connection structure along the first direction; depositing a dielectric layer and a sacrificial layer in the first portion; forming a second portion of the contact structure opening; and removing the sacrificial layer in the first portion of the contact structure through the second portion of the contact structure opening, where a size of the first portion of the contact structure opening along a second direction different from the first direction is greater than a size of the second portion of the contact structure opening along the second direction. The first portion of the contact structure opening can be, e.g., the initial contact structure opening 412 of FIGS. 4C-4F and 4O-4P. The dielectric layer can be, e.g., the second liner 418 of FIGS. 4G-4N. The sacrificial layer can be, e.g., the sacrificial structure 420 of FIGS. 4G-4N. The second portion of the contact structure opening can be, e.g., the upper opening 440 of FIGS. 4N-4P. The size of the first portion of the contact structure opening can be, e.g., the size 444 of FIG. 4O. The size of the second portion of the contact structure opening can be, e.g., the size 442 of FIG. 4O.

In some implementations, forming the contact structure includes: depositing the first conductive structure in the contact structure opening through the second portion of the contact structure opening; and depositing a second conductive structure in the contact structure opening through the second portion of the contact structure opening. The second conductive structure can be, e.g., the second conductive structure 264 of FIGS. 2A, 2C-3B and 4Q-4R.

In some implementations, depositing the first conductive structure including: depositing the first conductive structure by atomic layer deposition (ALD).

In some implementations, first openings are formed between adjacent first dielectric layers of the first dielectric layers in an initial memory array structure. Second openings are formed between adjacent first dielectric layers of the first dielectric layers in an initial connection structure. At least one conductive material is deposited in the first openings and the second openings to form the conductive layers. The first openings can be, e.g., the first openings 432 of FIG. 4J. The second openings can be, e.g., the second openings 436 of FIG. 4K. The initial memory array structure can be, e.g., the initial array structure 411 of FIGS. 4A-4K. The initial connection structure can be, e.g., the initial connection structure 409 of FIGS. 4A-4K.

FIG. 6 illustrates a block diagram of a system 600 having one or more semiconductor devices (e.g., memory devices), according to one or more implementations of the present disclosure. The system 600 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 6, the system 600 can include a host device 608 and a memory system 602 having one or more 3D memory devices 604 and a memory controller 606. Host device 608 can include a processor of an electronic device, such as a central processing unit (CPU), or a system-on-chip (SoC), such as an application processor (AP). Host device 608 can be configured to send or receive data to or from the one or more 3D memory devices 604.

A 3D memory device 604 can be any 3D memory device disclosed herein, such as the 3D semiconductor device 100 of FIG. 1, or a part of the 3D semiconductor device 100 (e.g., the second semiconductor device 200 of FIGS. 2A-2D, or the semiconductor device 300 of FIGS. 3A and 3B), or a structure at an intermediate fabrication process of the 3D semiconductor device 400 of FIGS. 4A-4R.

In some implementations, a 3D memory device 604 includes a NAND Flash memory. Memory controller 606 (a.k.a., a controller circuit) is coupled to 3D memory device 604 and host device 608. Consistent with implementations of the present disclosure, 3D memory device 604 can include a plurality of conductive interconnections through a cover layer that are in contact with conductive pads in a conductive pad layer, and memory controller 606 can be coupled to 3D memory device 604 through at least one of the plurality of conductive interconnections. Memory controller 606 is configured to control 3D memory device 604. For example, memory controller 606 may be configured to operate a plurality of channel structures 110 via word lines. Memory controller 606 can manage data stored in 3D memory device 604 and communicate with host device 608.

In some implementations, memory controller 606 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 606 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 606 can be configured to control operations of 3D memory device 604, such as read, erase, and program (or write) operations. Memory controller 606 can also be configured to manage various functions with respect to the data stored or to be stored in 3D memory device 604 including, but not limited to bad-block management, garbage collection, logical-to-physical address conversion, wear leveling, etc. In some implementations, memory controller 606 is further configured to process error correction codes (ECCs) with respect to the data read from or written to 3D memory device 604. Any other suitable functions may be performed by memory controller 606 as well, for example, formatting 3D memory device 604.

Memory controller 606 can communicate with an external device (e.g., host device 608) according to a particular communication protocol. For example, memory controller 606 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 606 and one or more 3D memory devices 604 can be integrated into various types of storage devices, for example, be included in the same package, such as a universal Flash storage (UFS) package or an eMMC package. That is, memory system 602 can be implemented and packaged into different types of end electronic products. In one example as shown in FIG. 6, memory controller 606 and a single 3D memory device 604 may be integrated into a memory card 602. Memory card 602 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some embodiments,” “some implementations,” “one implementation,” “an implementation,” “an example implementation,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+ conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layer 302s.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+−.10%, .+−.20%, or .+−.30% of the value).

As used in this disclosure, the term “substantially” or “substantial” refers to a majority of, or mostly, as in at least about 50%, 60%, 70%, 80%, 90%, 95%, 96%, 97%, 98%, 99%, 99.5%, 99.9%, 99.99%, or at least about 99.999% or more.

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

As used herein, the term “surrounded by” refers to at least partially surrounded by. For example, A is surrounded by B can refer to that A is at least partially surrounded by B.

As used herein, the term “and/or” as used herein refers to and encompasses any and all possible combinations of one or more of the associated listed terms. For example, the term “A and/or B” means that either option A, option B, or both options A and B are possible, where A and B may be singular or plural.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
a memory array structure comprising a first stack of first dielectric layers and conductive layers alternating with each other along a first direction and a channel structure extending in the first stack along the first direction;
a connection structure comprising a second stack of the first dielectric layers and second dielectric layers alternating with each other along the first direction; and
a contact structure extending at least partially in the connection structure along the first direction and comprising a first end, a second end and a step structure between the first end and the second end along the first direction, the first end being coupled to a corresponding conductive layer of the conductive layers of the first stack of the memory array structure,
wherein the step structure comprises a first surface and a second surface intersecting with the first surface, the first surface extends along a second direction different from the first direction and is between the first end and the second end along the first direction, and the second surface is in contact with the first end.

2. The semiconductor device of claim 1, wherein, along the second direction, a size of the second end is smaller than an outer size of the step structure.

3. The semiconductor device of claim 2, wherein the outer size of the step structure along the second direction is greater than a size of the first end along the second direction, and the size of the second end along the second direction is smaller than the size of the first end along the second direction.

4. The semiconductor device of claim 1, comprising: a slit structure extending along the first direction, wherein the slit structure comprises a first end and a second end opposite to the first end along the first direction, and a surface of the second end of the slit structure is aligned with the first surface of the step structure of the contact structure.

5. The semiconductor device of claim 1, wherein the contact structure comprises an air gap surrounded by at least one conductive structure.

6. The semiconductor device of claim 5, wherein the contact structure comprises a dielectric layer between the air gap and the at least one conductive structure.

7. The semiconductor device of claim 5, wherein the at least one conductive structure comprises a first conductive structure and a second conductive structure, and wherein the second end of the contact structure comprises a portion of the second conductive structure surrounded by a portion of the first conductive structure, both the portion of the second conductive structure and the portion of the first conductive structure extending along the first direction.

8. The semiconductor device of claim 7, wherein the second end of the contact structure comprises a dielectric layer surrounded by a portion of the second conductive structure.

9. The semiconductor device of claim 1, comprising:
a channel contact coupled to the channel structure, and a conductive material of the channel contact is same as a conductive material of the contact structure.

10. A semiconductor device, comprising:
a memory array structure comprising a first stack of first dielectric layers and conductive layers alternating with each other along a first direction and a channel structure extending in the first stack along the first direction;
a connection structure comprising a second stack of the first dielectric layers and second dielectric layers alternating with each other along the first direction; and
a contact structure extending at least partially in the connection structure along the first direction and comprising a first portion and a second portion, the first portion comprising a first end and a second end opposite to the first end along a first direction, the second end of the first portion being coupled to the second portion,
wherein a size of the first end of the first portion along a second direction different from the first direction is smaller than a size of the second end of the first portion along the second direction, and the size of the second end of the first portion is greater than a size of the second portion along the second direction.

11. The semiconductor device of claim 10, wherein the contact structure comprises an air gap surrounded by at least one conductive structure.

12. The semiconductor device of claim 11, wherein the contact structure comprises a dielectric layer between the air gap and the at least one conductive structure.

13. The semiconductor device of claim 10, comprising: a slit structure extending along the first direction,
wherein the slit structure comprises a first end and a second end opposite to the first end along the first direction, and a surface of the second end of the slit structure is aligned with a surface of the second end of the first portion of the contact structure.

14. The semiconductor device of claim 12, wherein the dielectric layer comprises a first part in the first portion of the contact structure and a second part in the second portion of the contact structure, and wherein the first part of the dielectric layer is in contact with the second part of the dielectric layer.

15. A method, comprising:
forming a memory array structure comprising a first stack of first dielectric layers and conductive layers alternating with each other along a first direction and a channel structure extending in the first stack along the first direction;
forming a connection structure comprising a second stack of the first dielectric layers and second dielectric layers alternating with each other along the first direction; and
forming a contact structure extending at least partially in the connection structure and comprising a first end, a second end and a step structure between the first end and the second end along a first direction, the first end being coupled to a corresponding conductive layer of the conductive layers,
wherein the step structure comprises a first surface and a second surface intersecting with the first surface, the first surface extends in a second direction different from the first direction and is between the first end and the second end, and the second surface is in contact with the first end.

16. The method of claim 15, comprising:
forming a channel contact extending in a dielectric interlayer on the memory array structure, the channel contact being coupled to the channel structure, and
wherein a conductive material of the channel contact is same as a conductive material of the contact structure.

17. The method of claim 16, comprising:
forming a contact structure opening extending in the connection structure;
forming a channel contact opening extending in the dielectric interlayer; and
depositing a first conductive structure in both the contact structure opening and the channel contact opening.

18. The method of claim 17, wherein forming the contact structure opening comprises:
forming a first portion of the contact structure opening extending in the connection structure along the first direction;
depositing a dielectric layer and a sacrificial layer in the first portion;
forming a second portion of the contact structure opening; and
removing the sacrificial layer in the first portion of the contact structure through the second portion of the contact structure opening,
wherein a size of the first portion of the contact structure opening along a second direction different from the first direction is greater than a size of the second portion of the contact structure opening along the second direction.

19. The method of claim 18, wherein forming the contact structure comprises:
depositing the first conductive structure in the contact structure opening through the second portion of the contact structure opening; and
depositing a second conductive structure in the contact structure opening through the second portion of the contact structure opening.

20. The method of claim 17, comprising:
forming first openings between adjacent first dielectric layers of the first dielectric layers in an initial memory array structure;
forming second openings between adjacent first dielectric layers of the first dielectric layers in an initial connection structure; and
depositing at least one conductive material in the first openings and the second openings to form the conductive layers.
